(19) United States
(12) Patent Application Publication
(10) Pub. No.: US 2013/0242558 A1
(43) Pub. Date: Sep. 19, 2013

(54) LUMINAIRE AND METHOD OF MANUFACTURING THE SAME

(71) Applicant: Makoto SAKAI, Kanagawa-ken (JP)

(72) Inventor: Makoto SAKAI, Kanagawa-ken (JP)

(73) Assignee: Toshiba Lighting & Technology Corporation, Kanagawa-ken (JP)

(21) Appl. No.: 13/480,885

(22) Filed: May 25, 2012

(30) Foreign Application Priority Data
Mar. 19, 2012 (JP) 2012-062523

(51) Int. Cl. F21S 4/00; H05K 13/00; F21V 15/01

(52) U.S. Cl. 362/249.02; 362/368; 29/592.1

(57) ABSTRACT

A luminaire according to one embodiment includes a light-emitting portion including a light-emitting element, a power control unit configured to supply power to the light-emitting portion, an external terminal connecting the power control unit and an external power source, and a ceramic housing having the power control unit housed therein, including the light-emitting portion mounted on one end side thereof and the external terminal mounted on the other end side thereof and configured to allow at least part of light radiated from the light emitting element to pass therethrough.

### CROSS-REFERENCE TO RELATED APPLICATIONS

This application is based upon and claims the benefit of priority from Japanese Patent Application No.2012-062523, filed on Mar. 19, 2012; the entire contents of which are incorporated herein by reference.

### FIELD

Exemplary embodiments described herein generally relate to a luminaire and a method of manufacturing the same.

### BACKGROUND

Luminaires having solid light-emitting elements such as light-emitting diodes (LEDs) as light sources become popular. The solid light-emitting elements may be used in luminaires for various applications owing to the small power consumption and the long lifetime thereof, In contrast, the solid light-emitting elements have the property that the light-emitting efficiency is lowered with increase in operating temperature. When the solid light-emitting elements are operated in a hot environment, the lifetime is shortened. Therefore, a thermal radiation design is important in the luminaires including the solid light-emitting elements employed therein.

However, with the design making the thermal radiation a primary concern, the size of a housing may be increased, and hence the light-distribution property may be limited. Therefore, a luminaire which achieves improvement both in thermal radiation and light-distribution property is required.

### BRIEF DESCRIPTION OF THE DRAWINGS

FIGS. 1A and 1B are schematic cross-sectional views illustrating a luminaire according to an embodiment;

FIG. 2 is a schematic drawing illustrating an outline of the luminaire;

FIGS. 3A and 3B are schematic drawings illustrating a casing of the luminaire;

FIG. 4 is a partial cross-sectional view schematically illustrating an engagement part of the luminaire; and

FIG. 5 is a schematic drawing illustrating an example of installation of the luminaire.

### DETAILED DESCRIPTION

A luminaire according to an embodiment includes a light-emitting portion including a light-emitting element, a power control unit configured to supply electric power to the light-emitting portion, an external terminal configured to connect the power control unit and an external power source, and a ceramic housing including the power control unit housed therein, the light-emitting portion mounted on one side of the ceramic housing and the external terminal mounted on the other side of the ceramic housing, and configured to allow at least part of light radiated from the light-emitting element to pass therethrough.

Referring now to the drawings, embodiments will be described below. For reference, the same components in the drawings are designated by the same reference numerals and detailed descriptions thereof are omitted as needed, and different parts will be mainly described.

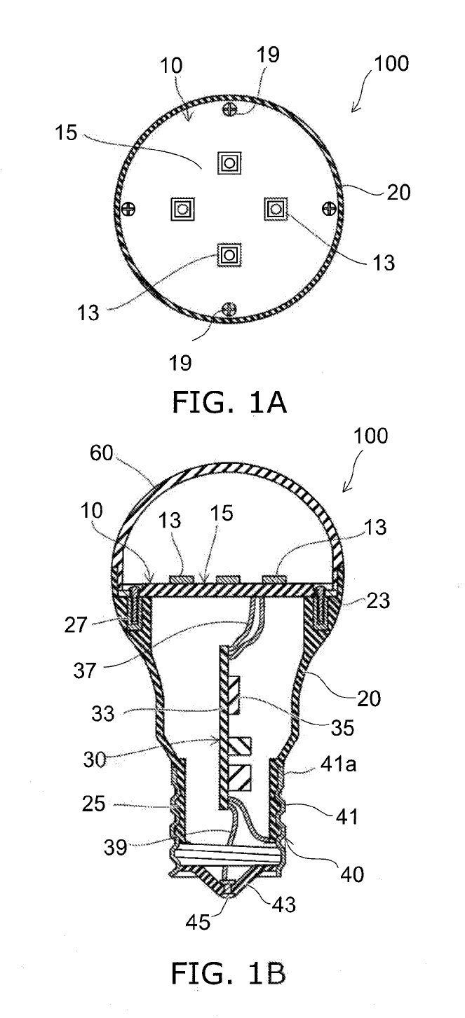

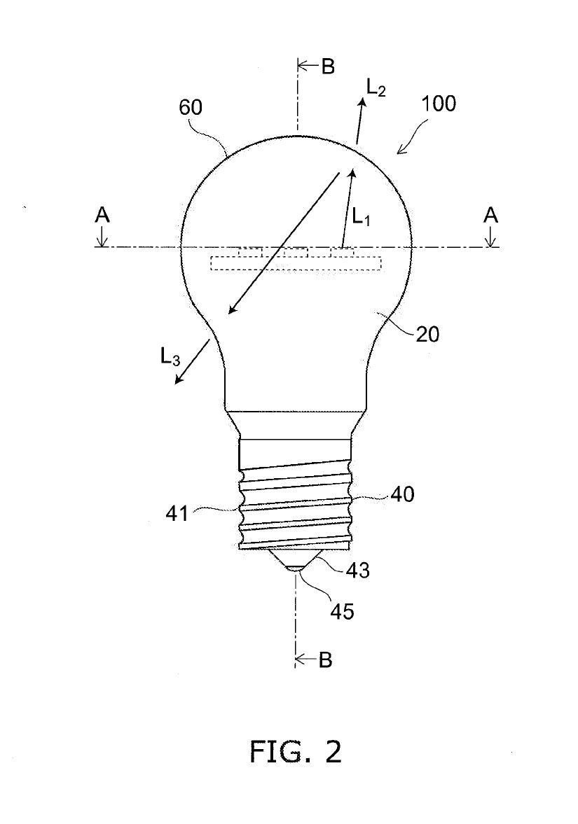

Referring now to FIGS. 1A, 1B and FIG. 2, a luminaire 100 according to an embodiment will be described. The luminaire 100 is a bulb type lamp including a solid light-emitting element. FIG. 1A is a cross-sectional view taken along the line A-A in FIG. 2, and illustrates a top view having a light-emitting portion 10 mounted thereon. FIG. 1B is a cross-sectional view taken along the line B-B in FIG. 2. FIG. 2 is a schematic drawing illustrating the outline of the luminaire 100.

The luminaire 100 includes a light-emitting portion 10 having a light-emitting element 13, a power control unit 30 configured to supply electric power to the light-emitting portion 10, and an external terminal 40 configured to connect the power control unit 30 and an external power source, not shown. The luminaire 100 further includes a ceramic housing 20 having the power control unit 30 housed therein and a cover 60 configured to cover the light-emitting portion 10.

The ceramic housing 20 includes a mounting portion 23 for the light-emitting portion 10 and a mounting portion 25 for the external terminal 40. The cover 60 is connected to one end of the ceramic housing 20 and covers the light-emitting portion 10. The ceramic housing 20 and the cover 60 both have translucency, and allow at least part of light radiated from the light-emitting element 13 to pass therethrough.

The light-emitting portion 10 includes at least one piece of the light-emitting element 13, and a base 15 to which the light-emitting elements 13 are secured. The base 15 preferably allows at least part of the light radiated from the light-emitting elements 13 to pass therethrough. The light-emitting elements 13 are sealed by resin containing a phosphor. For example, a white light source is achieved by sealing a blue LED by a resin containing a YAG phosphor.

Examples of the light-emitting element 13 includes a light-emitting diode (LED). When a gallium nitride (GaN)-based compound semiconductor is used as a material of an active layer, a short-wavelength light having a wavelength of 500 nanometer or less is obtained. However, the material of an active layer is not limited to the gallium nitride-based compound semiconductor.

Examples of the light-emitting element 13 include an organic light-emitting diode (OLED), an inorganic electro luminescence light-emitting element, an organic electro luminescence light-emitting element, or other electroluminescence-type light-emitting elements in addition to the light-emitting diode.

As shown in FIG. 1A, the light-emitting elements 13 are secured on the circular base 15. A material having a high coefficient of thermal conductivity is preferably used for the base 15. For example, a translucent resin substrate and a ceramic substrate may also be used. A sapphire substrate or a SiC substrate may be used.

A wiring pattern, not shown, is formed on an upper surface of the base 15, and four of the light-emitting elements 13 are mounted on the wiring pattern. The light-emitting elements 13 are, for example, LED chips, and are secured using silver (Ag) paste or an adhesive agent, and are connected to the wiring via a metallic wire. The light-emitting elements 13 may have a form stored in a package such as a SMD (Surface Mount Device).

The light-emitting portion 10 is secured to the mounting portion 23 of the ceramic housing 20 using fixing members 19 such as screws. The power control unit 30 is connected to the light-emitting portion 10.

As shown in FIG. 1B, the power control unit 30 is arranged in the interior of the ceramic housing 20, and electrically connected to the light-emitting portion 10 via a lead wire 37. The power control unit 30 is, for example, an AC-DC converter and configured to convert an AC voltage 100V to a DC voltage 24V and supplies a predetermined drive current to the light-emitting elements 13.

The power control unit 30 includes a circuit board 33 and an electronic component 35 to be mounted thereon. Then, the circuit board 33 preferably allows at least part of light radiated from the light-emitting elements 13 to pass therethrough. A translucent resin substrate and a ceramic substrate may be used as the circuit board 33, for example. A sapphire substrate or a SiC substrate may be used. The power control unit 30 is not limited to a positive circuit including a transistor and the like and, for example, may be a resistance which lowers a power source voltage so as to comply with a drive voltage of the light-emitting element 13.

The power control unit 30 is electrically connected to, for example, the external terminal 40 attached to the ceramic housing 20 via a lead wire 39. The external terminal 40 is a cap configured to engage a socket connected to the external power source. The external terminal 40 is an Edison Type E17-base cap, and includes a cylindrical shell portion 41 formed of a copper plate having a thread, and a conductive eyelet portion 45 provided via an electric insulating portion 43.

As shown in FIG. 1B, the shell portion 41 is fitted from the outside along the mounting portion 25 of the ceramic housing 20, and fixed to the mounting portion by adhesion with an adhesive agent such as a silicone resin or epoxy resin or by means of caulking. Then, the lead wire 39 is connected to the shell portion 41 and the eyelet portion 45 and is electrically connected to the power control unit 30.

In this manner, according to the embodiment, the structure of the luminaire 100 is simplified by using the ceramic housing 20. In other words, in the housing using a metal such as aluminum, an insulative case for isolating the power control unit 30 from the housing, or an insulative joint for joining the external terminal 40 and the housing is required. In contrast, in the insulative ceramic housing 20, the power control unit 30 and the external terminal 40 may be mounted directly, so that the number of components may be reduced to improve the production efficiency.

Furthermore, the luminaire 100 includes the cover 60 configured to cover the light-emitting portion 10. The cover 60 is so-called a globe of a bulb type lamp and, for example, a resin such as polycarbonate or glass may be used. Further preferably, a translucent ceramic material may be used. For example, the cover 60 includes at least one material selected from among sapphire, translucent polycrystalline alumina ceramic (aluminum oxidative product), yttrium-aluminum-garnet (YAG), yttrium oxide (YOx) and aluminum nitride (AlN).

By using translucent ceramic for the cover 60, the thermal radiation property of the luminaire 100 may be improved.

For example, the translucent ceramic has a higher coefficient of thermal conductivity than polycarbonate or glass, so that a larger thermal radiation from the cover 60 is achieved.

By using the translucent ceramic for both of the ceramic housing 20 and the cover 60, the durability at a joint portion between the ceramic housing 20 and the cover 60 may be improved.

In other words, by using the same type of material or the same material for both of the ceramic housing 20 and the cover 60, the values of the coefficients of linear thermal expansion may be brought close to each other, and a thermal stress applied to the joint portion may be reduced. For example, deterioration of the joint portion due to a heat cycle generated by turning ON and OFF repeatedly can be suppressed.

FIG. 2 is a schematic drawing illustrating the outline of the luminaire 100. The substantially semispherical cover 60 is attached to one end of the ceramic housing 20 and the external terminal 40 is attached to the other end of the ceramic housing 20.

Since both of the ceramic housing 20 and the cover 60 are formed of a translucent material, light L₁ radiated from the light-emitting element 13 is released to the outside through the cover 60 (L₂). In contrast, light L₃ reflected or scattered by the cover 60 and propagating in the direction toward the ceramic housing 20 is also released to the outside through the ceramic housing 20.

The term “through the ceramic housing 20” includes not only the linear propagation of light shown in FIG. 2, but also a case of propagating in the housing while scattering and being released to the outside.

In this manner, by using the translucent ceramic, the light shielding by the housing may be reduced. Also, the coefficient of thermal conductivity of the translucent ceramic is lower than that of metal, but a sufficient thermal radiation is secured in comparison with resin and glass. In addition, the structure of the ceramic housing is simpler than that of a metallic housing in which insulative members such as an insulative case is arranged in the housing, and hence a joint surface between the components may be reduced. From this point of view, improvement of thermal radiation is achieved.

In other words, in the embodiment, by using the translucent ceramic housing 20, the luminaire improved in both of the thermal radiation property and the light-distribution property is realized.

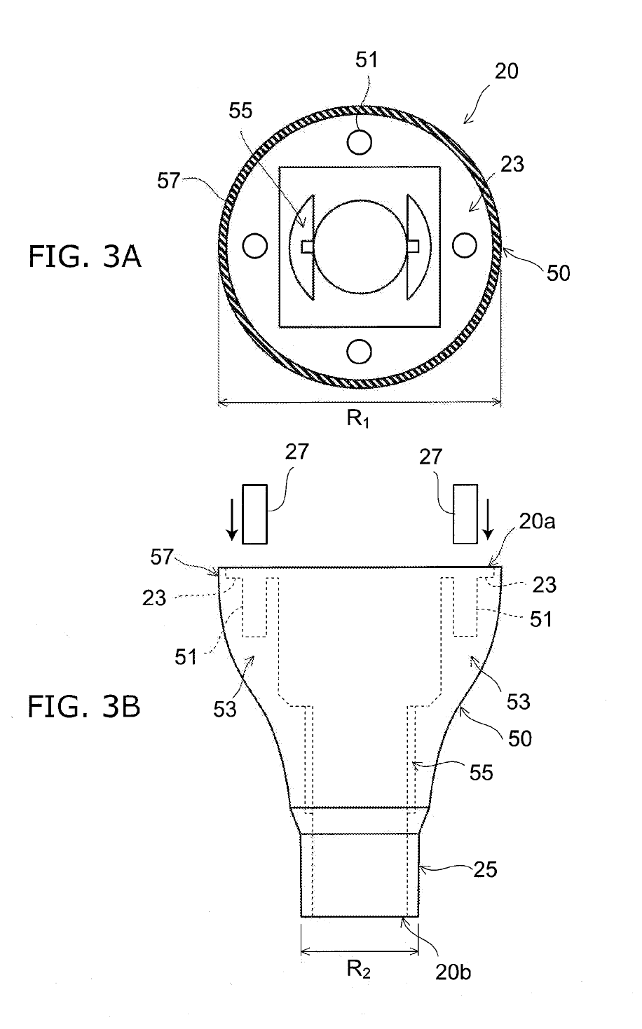

FIGS. 3A and 3B are schematic views illustrating the ceramic housing 20 according to the embodiment. FIG. 3A is a plan view illustrating one of the end surfaces to which the light-emitting portion 10 is mounted, and FIG. 3B is a side view.

The ceramic housing 20 is formed into a cylindrical shape, and includes the mounting portion 23 for the light-emitting unit 10 at one end 20a thereof and the mounting portion 25 for the external terminal 40 at the other end 20b thereof. In the embodiment, the ceramic housing 20 is formed into a cylindrical shape and the diameter R₁ of the one end 20a is larger than the diameter R₂ of the other end 20b.

The ceramic housing 20 has translucency and includes at least selected one of aluminum oxide, aluminum nitride, YAG, or yttrium oxide.

The thickness of the ceramic housing 20 is preferably between 0.5 mm to 3.0 mm inclusive. If the thickness is 0.5 mm or smaller, the yield of the molding process is lowered and the cost is increased. In contrast, if the thickness is increased to 3.0 mm or larger, the transmittance is lowered. A material price is increased, which increases the cost correspondingly.

For example, the ceramic material scatters light by grain boundary and pore (air holes) existing therein, and has a light-shielding property by impurities which absorb light. In other words, the ceramic material reduces the optical anisotropy of the material, and inhibits the scattering of light by reducing the number of pores. In addition, the light absorption may be inhibited by reducing the impurities contained in the material, whereby the transparency is improved.

In the embodiment, the light distribution is improved by releasing the light transmitted through the ceramic housing 20 to the outside. Therefore, the scattering of the light propagating in the interior of the ceramic housing 20 is allowed. In contrast, the light absorption of the ceramic material is preferably reduced to improve the transmittance of the ceramic housing 20.

For example, the light transmittance of the ceramic housing 20 is preferably 60% or higher and 95% or lower. In order to do so, the thickness of the ceramic housing 20 is reduced in a range from 0.5 mm to 3.0 mm inclusive, or the coefficient of light absorption of the translucent ceramic material is adjusted.

The ceramic housing 20 includes a thick portion 53, and the mounting portion 23 for the light-emitting portion 10 corresponds to an end surface of the thick portion 53. Then, as shown in FIG. 3A, the mounting portion 23 includes an opening 51.

In the process of molding of the ceramic housing 20, a cylindrical body 50 is primarily molded and, for example, the end 20a is cut out to form the opening 51.

Subsequently, engaging members 27 are inserted into the opening 51 and is sintered as shown in FIG. 3B. Then, the engaging members 27 are fixed to the interior of the opening 51 by contraction of the body 50 in the process of sintering.

The engaging members 27 are, for example, screw brackets, and engage screws for fixing the light-emitting portion 10. The engaging members 27 fixed by the process described above are stable for a heat cycle occurring by turning the luminaire ON and OFF repeatedly, and have reliability higher than connection using an adhesive agent.

The end 20a of the ceramic housing 20 includes a frame 57 formed along the outer periphery thereof. The frame 57 engages an end of the cover 60 and fixes the cover 60 to the ceramic housing 20.

Guides 55 configured to support the circuit board 33 are provided on an inner surface of the ceramic housing 20. The guides 55 are two grooves provided on the inner surface of the ceramic housing 20, and end portions of the circuit board 33 are inserted into the guides 55 respectively.

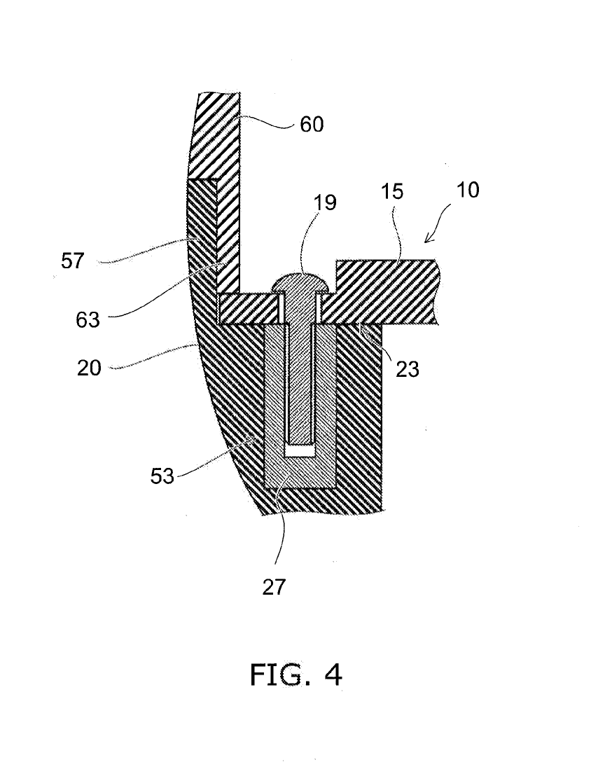

FIG. 4 is a partial cross-sectional view schematically illustrating the engaging portion which engages the light-emitting portion 10 and the ceramic housing 20.

The engaging member 27 is embedded into the mounting portion 23 of the light-emitting portion 10 provided on the one end 20a of the ceramic housing 20. The light-emitting portion 10 is fixed to the mounting portion 23 by the fixing members 19 which engage the engaging members 27.

More specifically, the engaging member 27 is, for example, a screw bracket, and configured to fix the end of the light-emitting portion 10 with a screw, which is the fixing member 19. As shown in FIG. 4, the back surface of the base 15 of the light-emitting portion 10 comes into surface contact with the mounting portion 23, and transfer of heat from the base 15 to the ceramic housing 20 is secured. As described above, the engaging member 27 is inserted into the opening 51 provided on the ceramic housing 20, and fixed thereto. Therefore, the reliability of the connection between the light-emitting portion 10 and the ceramic housing 20 is high, and stable thermal radiation from the light-emitting portion 10 to the ceramic housing 20 is secured.

As shown in FIG. 4, an end portion 63 of the cover 60 engages the frame 57 and is fixed by, for example, an adhesive agent. The frame 57 is provided along the outer periphery of the end 20a of the ceramic housing 20 and the entire circumference of the frame 57 comes into contact with the end portion 63 of the cover 60. Accordingly, the thermal radiation from the ceramic housing 20 to the cover 60 is improved.

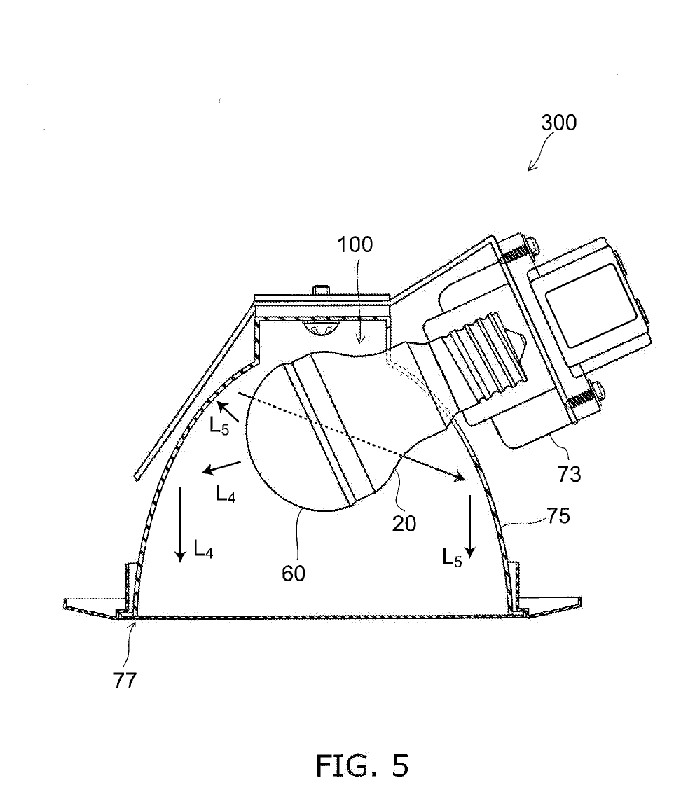

FIG. 5 is a schematic drawing illustrating an example of installation of the luminaire 100 according to the embodiment. As shown in the drawing, the luminaire 100 is mounted on a down-light type lighting apparatus 300. The lighting apparatus 300 includes a metallic mirror portion 75 having an opening 77 at the lower end and a socket 73. The luminaire 100 is connected to the external power source by screwing the external terminal 40 (cap) thereof into the socket 73.

When the socket 73 is energized and the luminaire 100 is illuminated, light L₄ emitted from the cover 60 is reflected from the inner surface of the mirror portion 75 and illuminates downward. Since the ceramic housing 20 has a translucency, light L₅ reflected from the mirror portion 75 and propagating in the direction toward the ceramic housing 20 passes through the ceramic housing 20 and illuminates downward.

In this manner, the light-distribution property is improved by providing the ceramic housing 20 with translucency, and hence the lighting apparatus 300 realizes uniform illumination which does not form a shadow of the housing.

Although several exemplary embodiments are described above, the embodiments are shown as examples and are not intended to limit the scope of the invention. These novel embodiments may be implemented in other various modes, and various omissions, replacements, and modifications may be made without departing the scope of the invention. The embodiments and the modifications are included in the scope and gist of the invention and are also included in the range of the following claims and their equivalents.

What is claimed is:

1. A luminaire comprising:
a light-emitting portion including a light-emitting element;
a power control unit configured to supply power to the light-emitting portion;
an external terminal configured to connect the power control unit and the external power source; and
a ceramic housing including the power control unit housed therein, the light-emitting portion mounted on one end side of the ceramic housing and the external terminal mounted on the other end side of the ceramic housing, and configured to allow at least part of light radiated from the light-emitting element to pass therethrough.

2. The luminaire according to claim 1, wherein the ceramic housing has a cylindrical shape.

3. The luminaire according to claim 1, further comprising an engaging portion provided on a mounting portion for the light-emitting portion and configured to fix the light-emitting portion to the ceramic housing.

4. The luminaire according to claim 3, wherein the engaging portion is a screw bracket embedded in the ceramic housing, and
the light-emitting portion is secured to the ceramic housing with a screw.

5. The luminaire according to claim 1, wherein the ceramic housing includes a portion that is thicker than other portions, and
a mounting portion of the light-emitting portion corresponds to an end surface of the thicker portion.

6. The luminaire according to claim 1, wherein the ceramic housing is formed into a cylindrical shape, and ends of the ceramic housing have different diameters.

7. The luminaire according to claim 1, wherein the ceramic housing includes at least one of aluminum oxide, aluminum nitride, YAG and yttrium oxide,

8. The luminaire according to claim 1, wherein the ceramic housing has a thickness from 0.5 mm to 3,0 mm.

9. The luminaire according to claim 1, wherein the ceramic housing has a light transmittance from 60% to 95%.

10. The luminaire according to claim 1, further comprising a cover connected to the ceramic housing and configured to cover the light-emitting portion, and containing a ceramic material which allows at least part of light radiated from the light-emitting element to pass therethrough.

11. The luminaire according to claim 10, wherein the cover contains the same ceramic material as the ceramic housing.

12. The luminaire according to claim 1, wherein the light-emitting portion includes one or more light-emitting elements and a base to which the light-emitting elements are secured, and
the base allows at least part of light radiated from the light-emitting elements to pass therethrough.

13. The luminaire according to claim 1, wherein the power control unit includes a circuit board and an electronic component mounted thereon, and
the circuit board allows at least part of the light radiated from the light-emitting elements to pass therethrough.

14. A method of manufacturing a luminaire having a ceramic housing of a cylindrical shape, comprising:
inserting an engaging member into a hole provided on one end of the ceramic housing having the cylindrical shape; and
fixing the engaging member to the one end of the ceramic housing by sintering.

15. The method according to claim 14, wherein the engaging member is a screw bracket, and a light-emitting portion including a light-emitting element is secured to the one end of the ceramic housing with a screw that is engaged with the screw bracket,

16. The method according to claim 15, wherein a ceramic cover is secured to the ceramic housing to cover the light-emitting element.

17. The method according to claim 16, wherein both the ceramic housing and the ceramic cover have a light transmittance of at least 60%.

18. A luminaire comprising:
a ceramic housing having opposing first and second ends;
one or more light-emitting elements mounted on the first end of the ceramic housing;
an external terminal configured to supply power to the light-emitting elements and mounted on and to the outer periphery of the second end of the ceramic housing; and
a ceramic cover attached to the ceramic housing to cover the light-emitting elements.

19. The luminaire of claim 18, wherein both the ceramic housing and the ceramic cover have a light transmittance of at least 60%.

20. The luminaire of claim 19, wherein the light-emitting elements are mounted on a base that is translucent.
